(19) United States
(12) Patent Application Publication
(10) Pub. No.: US 2006/0083280 A1
(43) Pub. Date: Apr. 20, 2006

(54) Method for producing multilayers on a substrate

(75) Inventors: Aurelie Tauzin, St. Martin Le Vinoux (FR); Philippe Gilet, Saint Quentin Sur Isere (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 11/247,268

(22) Filed: Oct. 12, 2005

(30) Foreign Application Priority Data
Oct. 19, 2004 (FR) 04 11075

(51) Int. Cl. H01S 5/00

(52) U.S. Cl. 372/46.01

(57) ABSTRACT

The invention relates to a method for producing a multilayer on a receiving substrate, including the following steps: the formation of an initial substrate comprising a first material layer formed on the surface of a supporting substrate made of a second material, molecular adhesion bonding of the surface of the initial substrate comprising the first material layer to the bonding surface of a receiving substrate to obtain a bonded structure, partial removal of the initial substrate so as to leave a thin film of said second material on the first material layer, evaporation of the second material thin film with a selective stop on the first material layer, growth of at least one layer from the first material layer bonded to the receiving substrate, with the evaporation step and the growth step being carried out in the same technological apparatus.

### TECHNICAL FIELD

This invention relates to a method for producing multilayers on a receiving substrate. This method makes it possible among other things to produce a resonant cavity structure comprising an active layer that transmits or detects light interposed between two reflecting mirrors.

### PRIOR ART

The production of multilayers (for example GaAs-type III-V multilayers) on a substrate is generally achieved by means of the following steps:
the production of a stack of layers by growth of a barrier layer (for example AlAs), then an active layer (for example GaAs) on a supporting substrate (for example GaAs),
the implantation of gaseous species such as H, He, noble gases, and so on in the supporting substrate,
bonding, by means of molecular adhesion, the stack to a receiving substrate (for example, made of silicon) to obtain a bonded structure,
fracturing the supporting substrate at the level of the implanted zone, which fracture is caused by a heat treatment and/or the application of mechanical stresses on the bonded implanted structure; this results in the supporting substrate (which can be reused), having a thin film been taken from it, and the receiving substrate onto which the active layer, the barrier layer and the thin film taken from the supporting substrate are transferred,
selective etchings of the thin film taken from the supporting substrate, and the barrier layer,
growth of multilayers (for example III-V) from the active layer transferred onto the receiving substrate; the growth can be achieved by epitaxy, for example.

According to the applications, the multilayers produced on the active layer arranged on the receiving substrate can then undergo various technical steps related to the production of a variety of devices, such as photovoltaic cells.

In this series of steps, it is the step of selective etching that raises a problem. Indeed, to be capable of obtaining high-quality multilayers compatible with the intended application, it is necessary for the thin film and the barrier layer to be integrally etched without the active layer being affected by this. In addition, if the active layer is to be compatible with epitaxial growth, its surface must be smooth and clean, of low roughness and without crystallographic defects or impurities.

According to document [1], the selective etching step can be performed by chemical attack. To do this, a solution is used to selectively etch the thin film with respect to the barrier layer, then a solution is used to selectively etch the barrier layer with respect to the active layer. The choice of chemical attack for carrying out the selective etchings has disadvantages. Indeed, this choice requires the use of two different chemical solutions specific to the type of layers to remove/preserve. Moreover, selective etching by chemical attack can cause defects in the active layer and/or modify its surface (for example, its roughness, etc.).

In addition, etching the thin film exposes the barrier layer. However, depending on its composition, the barrier layer can be damaged by contact with the air (for example, if the barrier layer is made of AlAs). In this case, this oxidation layer should be removed in an additional etching step which complicates the method for producing multilayers.

### DESCRIPTION OF THE INVENTION

We propose an original approach to the production of multilayers on a receiving substrate, which does not have the disadvantages mentioned above.

The invention relates to a method for producing a multilayer on a receiving substrate, which includes the following steps:
the formation of an initial substrate comprising a layer of a first material formed on the surface of a supporting substrate made of a second material, wherein the first material has a higher evaporation temperature than the evaporation temperature of the second material,
bonding, by means of molecular adhesion, the surface of the initial substrate comprising the first material layer to the bonding surface of a receiving substrate so as to obtain a bonded structure,
partially removing the initial substrate so as to leave a thin layer of said second material on the first material layer,
evaporating the second material thin film with a selective stop on the first material layer, which evaporation is carried out at a temperature higher than or equal to the evaporation temperature of the second material, and lower than the evaporation temperature of the first material,
growth of at least one layer from the first material layer bonded to the receiving substrate,

wherein the evaporation step and the growth step are carried out in the same technological apparatus. In other words, the growth and the evaporation are realised in the same technological apparatus (“epitaxy apparatus), i.e. without intermediate contact to the air. “Evaporation temperature of a material” means the temperature at which its evaporation rate becomes significant (typically around several nanometers per minute).

Advantageously, the second material supporting substrate is a second material substrate or a second material layer formed on a predetermined substrate.

The method also advantageously includes, before the bonding step, a step of forming at least one additional layer on the first material layer. This at least one additional layer can serve among other things as a protective layer for the first material layer. This can also be a bonding layer (for example made of SiO₂).

Advantageously, the receiving substrate also comprises at least one layer on its bonding surface, for example made of SiO₂.

Advantageously, the surface of the second material supporting substrate comprising the first material layer and/or the bonding surface of the receiving substrate further comprise(s) a Bragg mirror consisting of an alternation of thin films with different refraction indices n₁ and n₂.

According to a specific embodiment, the step of partially removing the initial substrate is performed by implanting, prior to the bonding step, gaseous species in the second material supporting substrate, and by performing thermal annealing of the bonded implanted structure obtained, at a temperature below the evaporation temperature of the second material and/or by applying mechanical stresses to the bonded implanted structure. This results in the supporting substrate, which can be recycled, having a thin film been taken from it, and the receiving substrate onto which the thin film taken from the supporting substrate, as well as the first material layer, are transferred.

The gaseous species used for the implantation are advantageously H or He ions, noble gases.

According to another specific embodiment, the step of partially removing the initial substrate is performed by mechanical-chemical thinning of said initial substrate until a second material thin film is obtained on the first material layer.

Advantageously, the step of growing said at least one layer on the first material layer is performed by molecular beam epitaxy (MBE) or by metal organic chemical vapour deposition (MOCVD), or by plasma enhanced chemical vapour deposition (PECVD). Other types of deposition can be performed (cathode sputtering, electron beam deposition, IBS (Ion Beam Sputtering), and so on).

The first material is advantageously AlAs, Si, etc.

The second material is advantageously GaAs, SiₓGe₁₋ₓ, InP, Ge, and so on.

The receiving substrate is advantageously made of a material selected from silicon, glass and ceramic, or any other medium suitable for the intended use.

Advantageously, the at least one layer formed on the bonded first material layer is made of a material selected from GaAs, AlAs, Si, SiGe or SiO₂, and so on. A III-V bilayer can thus be obtained.

The invention also makes it possible to obtain resonant cavity structures. The invention thus relates to a resonant cavity structure including an active layer, which transmits or detects light, interposed between two reflecting mirrors, wherein said structure is created using the method of production of the invention.

Advantageously, the two reflecting mirrors are Bragg mirrors obtained from thin films of which the materials are selected from Si₃N₄, SiO₂, TiO₂, Si or HfO₂.

The method for producing multilayers according to the invention has a number of advantages.

First, the step of evaporating the thin film and the step of growing the at least one layer on the first material layer are performed in the same epitaxy apparatus. The use of the same apparatus for these two steps limits the amount of equipment necessary, and therefore the costs. It minimises the handling and movement of plates, thus reducing the risks of damage.

The structure consisting of the receiving substrate, the first material film and the second material thin film can be considered to be “epi ready”, in the sense that this structure does not require a chemical preparation of its surface before it is inserted into the epitaxy apparatus or reactor: the removal of the second material thin film is performed by a thermal step before the epitaxial growth step.

The surface of the first material layer on which the growth of at least one layer is performed is protected (because it is embedded) throughout the process. Therefore, it undergoes no physical or chemical change, which is favourable for the growth of high-quality multilayers.

Unlike the prior art, the first material layer, which corresponds to the barrier layer of the prior art, is not in contact with the air: it remains in a controlled atmosphere. Therefore it is not damaged. Thus, it is not necessary to remove it to grow the multilayers, and the method is consequently simplified.

The at least one layer formed on the bonded first material layer can be obtained regardless of the growth method used: it can be obtained by molecular beam epitaxial growth or by metal organic chemical vapour deposition (MOCVD) or by PECVD. The thickness of this layer (or these layers) is therefore perfectly controlled and, more generally, the thickness of the entire stack made from this layer. Indeed, no chemical etching or polishing step is performed, as these steps are by nature less precise than the epitaxy or deposition steps.

### BRIEF DESCRIPTION OF THE DRAWINGS

The invention can be better understood, and special features will become apparent, in the reading of the following description, given as a non-limiting example, accompanied by the appended drawings in which:

FIGS. 1A to 1F show the steps of producing a multilayer on a substrate according to the invention,

FIGS. 2A to 2E show the steps of producing another multilayer on a substrate according to the invention,

FIGS. 3A to 3E show the steps of producing a multilayer including a Bragg mirror according to the invention,

FIGS. 4A to 4E show the steps of another example of the production of a multilayer including a Bragg mirror according to the invention.

It should be noted that the sizes of layers and substrates in these figures are not shown to scale.

### DETAILED DESCRIPTION OF SPECIFIC EMBODIMENTS

In a first embodiment, we will describe in detail the steps for producing a GaInP/GaAs/AlAs/GaAs/Si₃N₄/SiO₂ multilayer on a Si receiving substrate.

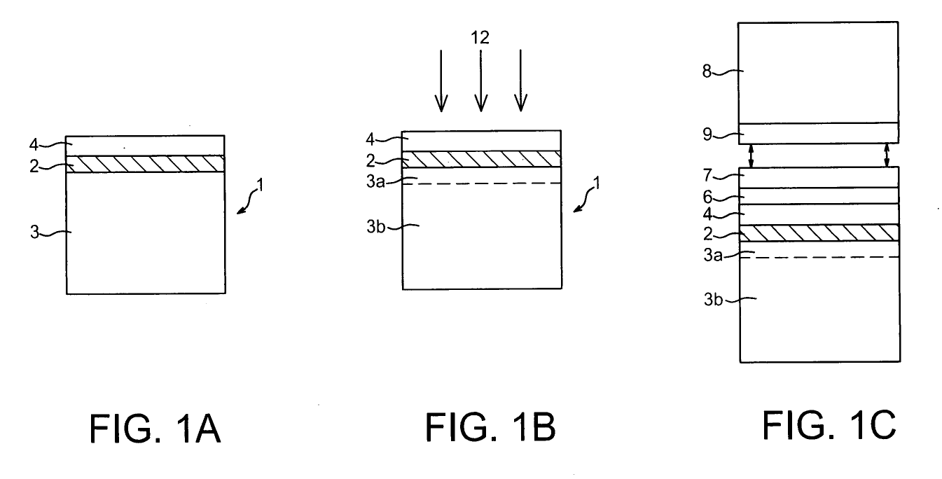

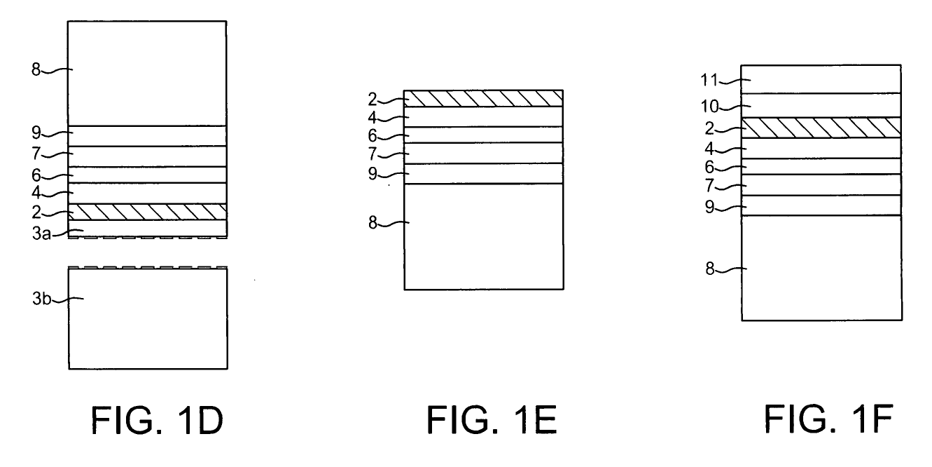

First, an initial substrate 1 is formed, comprising a supporting GaAs substrate 3 on which a first AlAs material layer 2 with a thickness of 100 nm is grown, for example by molecular beam epitaxy, then an additional GaAs layer 4 with a thickness of 150 nm is grown on the first material layer (FIG. 1A). The procedure for producing a layer of material having a predetermined thickness by means of molecular beam epitaxy is well known to a person skilled in the art. It would also be possible to deposit these layers by means of MOCVD.

To perform the step of partial removal of the initial substrate 1, the Smart Cut method is used, i.e. an implantation of gaseous species, followed, for example, by thermal annealing, which produces a fracture at the level of the implanted zone. Therefore, an implantation 12 of gaseous species in the GaAs supporting substrate 3 (on the surface including the first material layer 2) is performed. The supporting substrate 3 is then separated into two parts 3a and 3b on each side of the implanted zone (FIG. 1B).

The implantation energy must be high enough for the implanted zone to be located in the GaAs supporting substrate 3: the implantation depth must be greater than the thickness of the stack formed by the first AlAs material layer 2 and the additional GaAs layer 4. Typically, if this stack has a thickness of around 250 nm, an energy of around 100 KeV can be chosen.

In addition, the ion dose must be adequate for a fracture to occur at the level of the implanted zone, under heat activation and/or under the application of mechanical stresses. The ion dose should not, however, be higher than the critical dose beyond which blistering of the implanted supporting substrate 3 is observed. Typically, H⁺ ions are used and the implanted dose is between 6.10¹⁶ H⁺/cm² and 1.10¹⁷ H⁺/cm².

The implantation temperature is a critical parameter that determines whether or not a fracture is produced at the level of the implanted zone, under heat activation, and optionally with the application of mechanical stresses. Unlike in the case of Si or SiC, the implantation temperature of the GaAs must be within a very narrow window (between 160° C. and 250° C.).

Once the implantation has been completed, the bonding by molecular adhesion between the surface of the initial substrate 1, in this case comprising at its surface the additional GaAs layer 4, and the bonding surface of a receiving substrate 8 which will act as a stiffener is performed. Indeed, the Smart Cut method may require the layer to be transferred to be bonded with a stiffener 8 (for example, a silicon substrate), so as to enable the full plate fracture phenomenon to take place. In this case, the receiving substrate 8 is made of silicon. The bonding by molecular adhesion of the additional GaAs layer 4 with the silicon substrate can be achieved by performing a chemical cleaning of the surface of the GaAs layer 4, followed by a deposition of a Si₃N₄ layer 6 with a thickness of 100 nm on the GaAs layer and of a SiO₂ layer 7 also having a thickness of 100 nm. Then, a mechanical-chemical polishing of the surface of the SiO₂ layer is performed and this layer is placed in contact with a SiO₂ layer 9 having a thickness of 200 nm arranged on the silicon receiving substrate 8. The SiO₂ layer 9 of the silicon receiving substrate 8 can also undergo a mechanical-chemical polishing step so as to facilitate the molecular adhesion bonding. This results in a bonded structure formed by a stack including the second material supporting substrate 3, the first material layer 2, the additional layer 4, the Si₃N₄ layer 6, the SiO₂ layer 7, the SiO₂ layer 9 and the receiving substrate 8 (FIG. 1C).

Next, the initial substrate 1 is fractured at the level of the implanted zone located in the supporting GaAs substrate 3. This fracture can be made only if the bonded receiving substrate 8 performs its role as a stiffener.

The fracture can then be produced, for example, by annealing the bonded structure. The temperature of the annealing is chosen so that a fracture is produced at the level of the implanted zone, but also to reinforce the molecular adhesion bonding. Typically, the bonding can be achieved, for example, at room temperature, the annealing to strengthen the bonding can be performed at 150° C. and the fracture can be produced at 250° C. In particular, it is necessary to take into account the mechanical compatibility between the two substrate materials (the initial substrate and the receiving substrate) which impose their curves on the thin films that they support. For example, it is necessary to take into account their expansion and elasticity coefficients, etc., so as to prevent the plates from breaking and/or dislocations from forming when the temperature of the bonded structure rises. Moreover, for the fracture to be produced, it is necessary for the microcavities created by the implantation in the GaAs supporting substrate 3 to have time to grow in order to weaken the material. The GaAs supporting substrate can be fractured, for example, by RTA (rapid thermal annealing) at 250° C. of the bonded structure, optionally in combination with the application of mechanical stresses (for example, by inserting a blade between the two substrates). The fracture results in the transfer of the GaAs/AlAs/GaAs/Si₃N₄/SiO₂ layers to the silicon receiving substrate, with the remainder of the GaAs supporting substrate 3b then being capable of being recycled and subsequently reused (see FIG. 1D).

In an epitaxy apparatus, the GaAs thin film 3a can then be removed by evaporation at around 650° C. under an arsenic flux, with a selective stop on the first AlAs material layer 2 (FIG. 1E). The AlAs layer can then, in the same epitaxy apparatus, initiate the growth of one or more layers of material such as GaAs, GaAlAs, GaInP, GaAsN or any other layer with a lattice parameter similar to that of AlAs. It is important to note that this first AlAs material layer 2 is never exposed to air, thus preventing any pollution and in particular any oxidation of its surface.

Thus, one or more layers can be grown from the first AlAs material layer modified by the evaporation step. In the example shown in FIG. 1F, a GaAs layer 10 is grown, then a GaInP layer 11 is grown on the AlAs layer so as to produce solar cells, for example. The epitaxy can start directly with a GaAs layer at 600° C. in a molecular beam epitaxy apparatus or at 650-700° C. for a MOCVD apparatus, with the evaporation step having been carried out previously in the same apparatus. A GaInP layer can then be grown on the GaAs layer.

GaAs is a good option for forming the second material thin film (coming from the second material supporting substrate) and AlAs is a good option for the first material layer. Indeed, GaAs and AlAs have very distinct evaporation temperatures. GaAs starts to evaporate significantly at 650° C. while AlAs does at 700° C. The second material thin film is advantageously evaporated under arsenic back-pressure so as to prevent damage to the first material. Thus, by evaporating GaAs (preferably under an arsenic flux) at a temperature higher than or equal to 650° C. but below 700° C., it is possible to entirely remove the second material thin film without affecting the first material layer, i.e. to selectively stop at the AlAs layer.

According to another example, we will produce a SiO₂/Si/thin film multilayer on a silicon substrate with a silicon film that can be very thin (less than or equal to 5 nm).

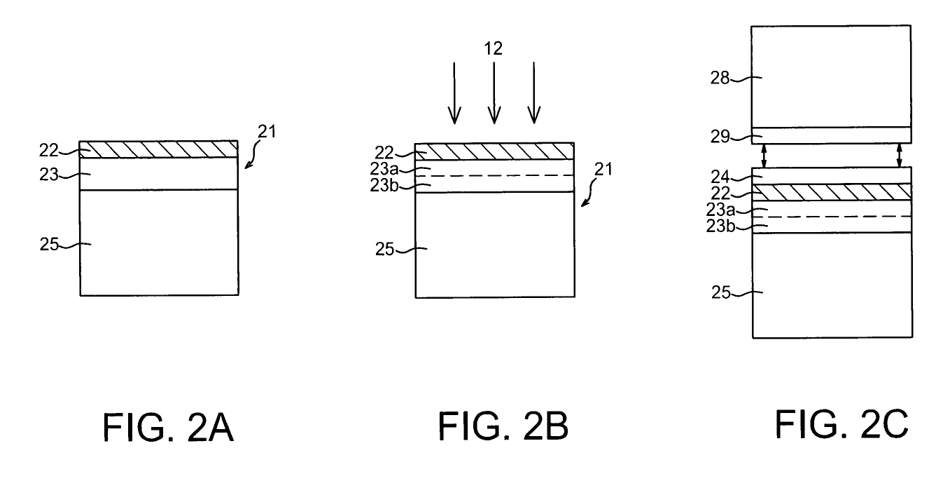

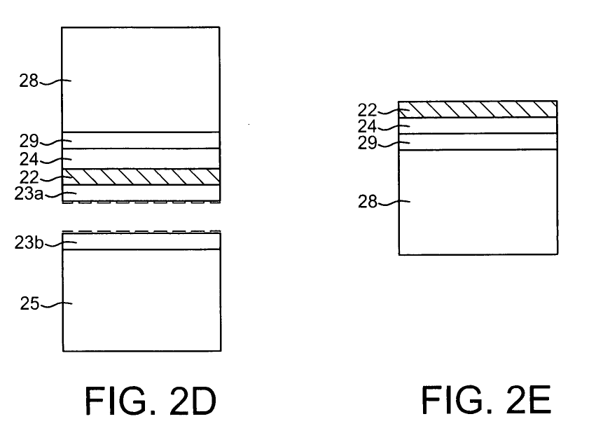

First an initial substrate 21 is prepared by growing a SiO_{0.7}Ge_{0.3} layer 23 having a thickness of 1 μm on a silicon substrate 25, then a Si layer 22 having a thickness of 5 nm is formed on the SiO_{0.7}Ge_{0.3} layer (FIG. 2A). In this case, the first material Si layer 22 is deposited on a supporting substrate consisting of a second material SiO_{0.7}Ge_{0.3} layer 23 deposited on a predetermined Si substrate 25.

This example includes the step of partially removing the initial substrate by using the Smart Cut method so as to obtain a thin film 23a of a second material SiO_{0.7}Ge_{0.3}. Therefore, light ions 12 are implanted in the SiO_{0.7}Ge_{0.3} layer 23 (FIG. 2B). For example, H⁺ ions at an energy of 40 KeV and a dose of 5.10¹⁶ to 1.10¹⁷ H⁺/cm² can be implanted.

Then the initial substrate 21 is bonded by molecular adhesion to a silicon receiving substrate 28, for example, according to the following steps (FIG. 2C):
deposition of a SiO₂ layer 24 on the first material Si layer 22 of the initial substrate,
mechanical-chemical polishing of this SiO₂ layer 24,
placing this SiO₂ layer 24 in contact with the silicon receiving substrate comprising a SiO₂ layer 29 on its bonding surface.

The bonding of the SiO₂ layer 24 with the receiving substrate can advantageously be reinforced by a heat treatment at 200° C.

Next, the bonded structure is fractured at the level of the implanted zone, for example, by performing annealing at 500° C., optionally in combination with the application of mechanical stresses (for example, by inserting a blade between the initial substrate and the receiving substrate) (FIG. 2D). The fracture results in the transfer of the SiO_{0.7}Ge_{0.3}/Si/SiO₂ layers to the receiving substrate, with the remainder of the initial substrate comprising the predetermined Si substrate 25 and the remaining layer 23b of Si_{0.7}Ge_{0.3} then capable of being recycled.

According to FIG. 2E, the evaporation step is then performed on the second material thin film 23a of SiO_{0.7}Ge_{0.3} with a selective stop on the first material Si layer 22. An ultra-thin substrate SOI (“Silicon on Insulator”) is thus obtained. It is important to note that this process allows for complete control over the thickness of the Si film of the SOI structure because its thickness results from an epitaxy step and not from a polishing or chemical attack step.

One or more layers can then be grown on the exposed Si layer 22, for example, a SiGe-doped silicon layer, an oxide, a nitride, a dielectric or other depending on the intended application, with the evaporation taking place in the same apparatus as that used for the growth of the layer(s).

We will now describe in detail two embodiments of a multilayer obtained according to the method of the invention and having a Bragg mirror.

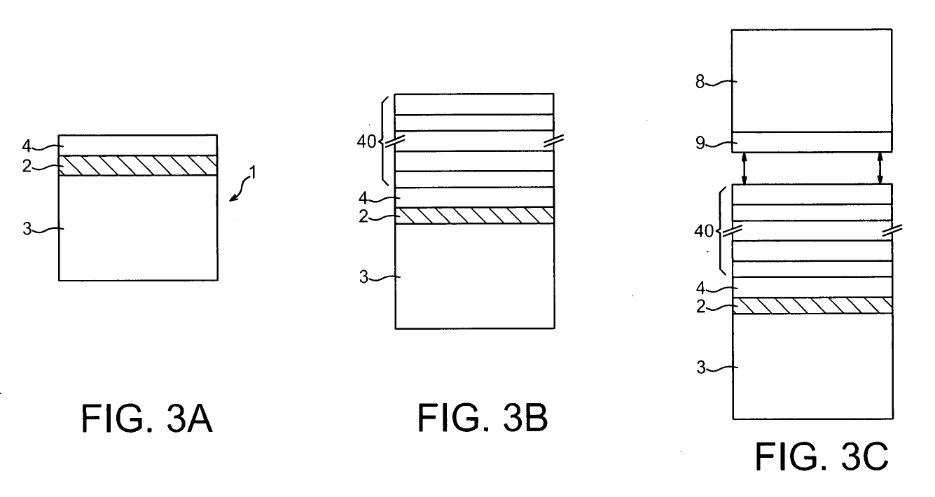

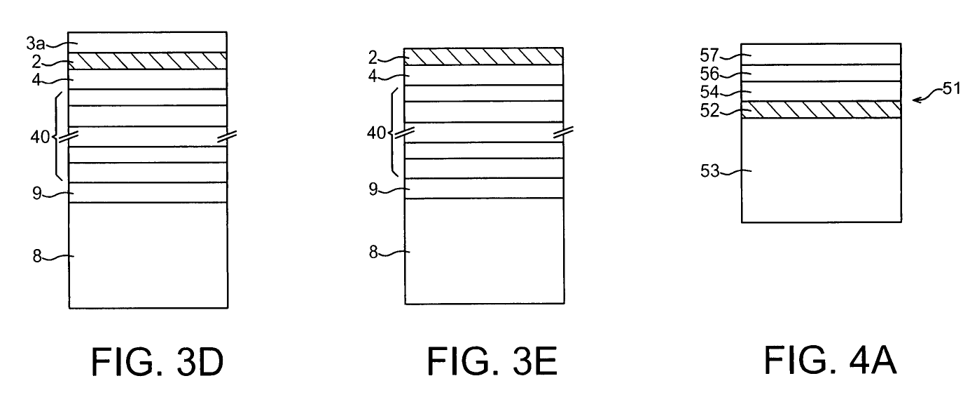

An initial substrate 1 is produced, comprising a second material supporting substrate 3, for example, made of GaAs, on which a first material AlAs layer 2 with a thickness of 10 nm is formed, on which an additional GaAs layer 4 with a thickness of 150 nm is then deposited (FIG. 3A).

A Bragg mirror 40 is then produced on the initial substrate 1 by depositing, on the additional GaAs layer 4, an alternated stack of thin films with refraction indices n₁ and n₂, with n₁ and n₂ being different (FIG. 3B). It is thus possible to use the following pairs of materials: Si₃N₄/SiO₂, TiO₂/SiO₂, Si/SiO₂ or HfO₂/SiO₂ to create a Bragg mirror. In this example, 20 layers of Si₃N₄ and SiO₂ with respective thicknesses of 162.5 nm and 221.7 nm are deposited to produce a mirror with a maximum reflectivity obtained at 1300 nm. It is a Si₃N₄ layer that is first deposited on the additional GaAs layer.

Next, the bonding of the structure including the Bragg mirror with a receiving substrate is performed. For example, the bonding can be performed by oxide-oxide molecular adhesion using a silicon receiving substrate 8 on which a SiO₂ layer 9 has previously been deposited. This SiO₂ layer 9 will thus adhere to the SiO₂ layer of the Bragg mirror 40 (FIG. 3C).

The partial elimination of the GaAs supporting substrate 3 is then carried out so as to leave a thin GaAs film 3a on the bonded structure (FIG. 3D). The (incomplete) removal of the GaAs substrate is carried out by the Smart Cut method (in this case, gaseous species must have been previously implanted in the supporting substrate 3, and then, for example, thermal annealing of the bonded structure must be performed to fracture the structure at the level of the implanted zone), or by thinning the supporting substrate 3, for example by mechanical-chemical polishing. The Smart Cut method has the advantage of leaving a supporting substrate that can be recycled and subsequently reused.

The thin GaAs film 3a retained on the bonded structure is then evaporated in an epitaxy apparatus (FIG. 3E), and the epitaxy of at least one active layer on the modified AlAs layer 2 can then be carried out. The precision on the thickness of the active epitaxial layers is thus less than 1% (it is limited only to the resolution of the epitaxy).

The example was provided with GaAs as the second material. This can be extended to include other substrates such as InP, Germanium, and so on. In the example above, the Bragg mirror is deposited on the initial substrate 1 on the additional GaAs layer 4. The Bragg mirror could also have been deposited on a receiving substrate and not on the initial substrate, as will be shown in the following example.

We will describe another way in which to produce the aforementioned multilayer.

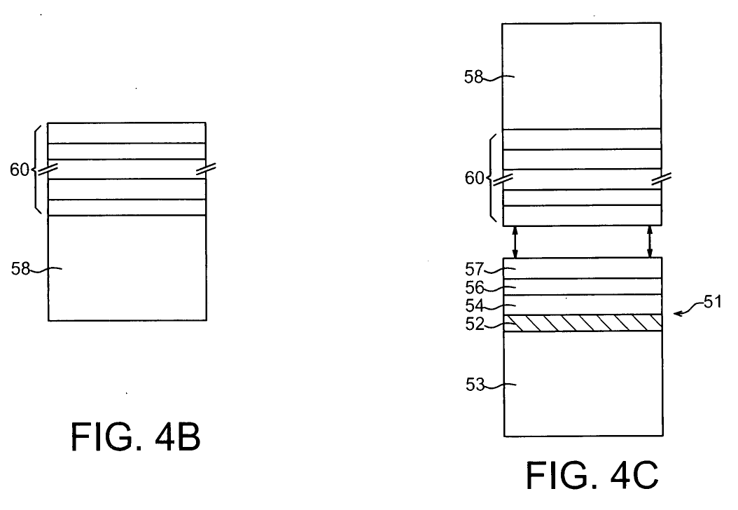

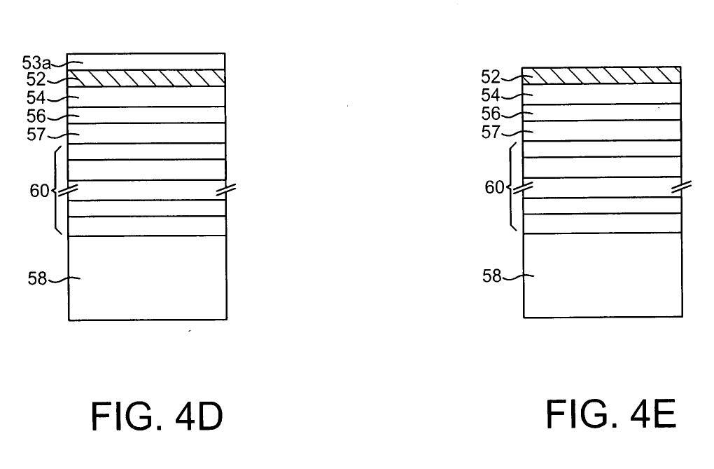

According to FIG. 4A, an initial substrate 51 is prepared by depositing an AlAs barrier layer (first material layer 52) with a thickness of 3 nm on a GaAs supporting substrate 53. An additional GaAs layer 54 with a thickness of 150 nm is also deposited on the first material layer 52: the AlAs layer 52 is thus protected by the additional GaAs layer 54. A Si₃N₄ layer 56 and a SiO₂ layer 57 are also deposited on the additional GaAs layer 54 (these two added layers 56, 57 will allow for the subsequent bonding of the initial substrate with the Bragg mirror deposited on the receiving substrate).

On a receiving substrate 58 made of silicon, for example (or glass, ceramic, etc.), a Bragg mirror is produced by dielectrically depositing thin films with different refraction indices (FIG. 4B). In this example, the Bragg mirror is the same as in the previous example. In this case, it is a SiO₂ layer that is first deposited on the Si receiving substrate.

The Bragg mirror 60 on its silicon substrate 58 is then bonded to the initial substrate 51 (FIG. 4C) by molecular adhesion. The bonding by oxide-oxide molecular adhesion of the SiO₂ layer 57 of the initial substrate with a SiO₂ layer provided on the Bragg mirror 60 can then be carried out without a phase-shifting step (the thickness is equal to λ/2).

It is specified that the mirror is completed with a Si₃N₄ layer because the stacking was started with a SiO₂ layer.

As in the previous example, the (incomplete) removal of the GaAs supporting substrate 53 is performed by thinning the supporting substrate until a bonded structure with a thin GaAs film 53a on its surface is obtained (FIG. 4D).

When it is ready for epitaxy, the bonded structure is placed in the epitaxy apparatus and the thin GaAs film 53a is evaporated (FIG. 4E).

Finally, the epitaxial growth of at least one layer (active layer) on the first material AlAs layer 52 is carried out.

The last two examples presenting a Bragg mirror 40, 60 will enable so-called resonant cavity structures to be produced. The principle of so-called resonant cavity structures consists of interposing an active layer that transmits or detects light between two reflecting mirrors or Bragg mirrors. The reflectivity of the mirrors used is generally relatively high (>95%). Some common examples of resonant cavity structures include vertical cavity surface-emitting lasers (VCSEL) or resonant cavity photodetectors.

The active layer is generally produced by epitaxy of an active material on a single crystal support. The problem lies in particular in the fact that the single crystal support in this case is the lower mirror which itself is commonly produced by epitaxy on a substrate. However, given the desired reflectivity of the mirrors (>95%), it is necessary to produce so-called “quarter wave” Bragg mirrors, in which the semiconductor layers forming the mirror have an optical thickness four times less than the wavelength at which the mirror must reflect light. The layers forming the Bragg mirror must therefore have very specific thicknesses. In addition, to obtain high reflectivity and taking into account the minor differences in indices observed between the materials commonly used and compatible with one another (for example 2.9 for AlAs and 3.5 for GaAs at 1.3 micrometers), the number of alternations n is generally high (over 20). It is noted that a Bragg mirror is formed by a number n of bilayers with different indices n₁ and n₂. This high number of alternations is detrimental and makes it necessary to have complete control over the epitaxy.

Moreover, for the resonant cavity structure to be of high quality, the precision of the thickness of the layers, in particular those close to the cavity, is important: this precision must be around 1 percent.

The method according to the invention makes it possible to eliminate the step of epitaxial growth of a lower Bragg mirror, which growth is difficult and limiting.

In addition, some materials, such as InP, for example, do not make it possible to grow the materials forming effective Bragg mirrors by epitaxy. It is then necessary to transfer, using bonding techniques, mirrors produced in other ways in order to benefit from the advantages of the different materials. However, to be effective, the active layer, with generally has a thickness of around 1 micrometer, must be located as close as possible to the Bragg mirrors. The step of bonding, in particular the active layer, must therefore be perfectly controlled, which is very difficult.

By using the method according to the invention, these disadvantages are avoided because the bonding is carried out before the epitaxy of the active material. This method may make it possible to obtain a precision on the thickness of the layers that is compatible with the requirements of the components (i.e. around 1 percent).

To form the lower or upper mirror, dielectric materials (for example Si/SiO₂) are preferably used because this makes it possible to reduce the number of alternations necessary to obtain a Bragg mirror with high reflectivity. For example, to obtain the same reflectivity, a Bragg mirror can be made using 5 Si/SiO₂ bilayers instead of 25 GaAs/AlAs bilayers. This is because the Si/SiO₂ system has a greater index difference between these components.

We will now describe in detail the production of a resonant cavity structure including an active layer between a lower Bragg mirror and an upper Bragg mirror made of Si₃N₄/SiO₂. This active layer can consist of a GaAs/GaInAsN stack or an alloy including Ga, In, N, Al, As, P, Sb.

By following the steps shown in FIGS. 3A-3D (or 4A-4D), a bonded structure is obtained, comprising a Si receiving substrate 8 (serving as a mechanical support) with a stack including a silica layer 9, a Bragg mirror 40 consisting of an alternation of Si₃N₄/SiO₂ bilayers, a GaAs layer 4 (additional layer), a AlAs layer 2 (first material barrier layer) and a thin GaAs film 3a (second material layer). This bonded structure is placed in an epitaxy apparatus and the thin GaAs film 3a is evaporated (FIG. 3E). The AlAs barrier layer 2 is then exposed and the epitaxy can be started on this layer. In this case, the epitaxy of one or more active layers on the AlAs layer 2 is performed on top of a Bragg mirror with complete control over the thicknesses. The control is achieved by means of the AlAs layer which has an evaporation temperature higher than the second material layer, which in this example is made of GaAs.

Once the cavity is formed by the deposition of the active layer, the upper dielectric mirror including Si₃N₄/SiO₂ bilayers simply has to be deposited, for example, by PECVD. The active layer can be formed, for example, by a GaAs/GaInNAs stack.

The two mirrors are preferably dielectric (Si/SiO₂, HfO₂/SiO₂, TiO₂/SiO₂ and so on). The two mirrors are not necessarily identical.

The technological method is then carried out. For more details on this method, reference can be made to document [2].

### BIBLIOGRAPHY

[1] K. D. Hobart et al., “Ultra-cut: A simple technique for the fabrication of SOI substrates with ultra-thin (<5 nm) silicon films”, Proceedings, 1998 IEEE International SOI Conference, October 1998.
[2] “Vertical-Cavity Surface-Emitting Lasers”, edited by Carl Wilmsen, Henryk Temkin and Larry A. Coldren, p. 193-225, p. 203-325, Cambridge University Press, 1999.

1. Method for producing a multilayer on a receiving substrate, which method includes the following steps:
the formation of an initial substrate comprising a first material layer formed on the surface of a supporting substrate made of a second material, wherein the first material has an evaporation temperature higher than the evaporation temperature of the second material,
molecular adhesion bonding of the surface of the initial substrate comprising the first material layer to the bonding surface of a receiving substrate to obtain a bonded structure,
partial removal of the initial substrate so as to leave a thin film of said second material on the first material layer,
evaporation of the second material thin film with a selective stop on the first material layer, which evaporation is carried out at a temperature higher than or equal to the evaporation temperature of the second material, and lower than the evaporation temperature of the first material,
growth of at least one layer from the first material layer bonded to the receiving substrate, with the evaporation step and the growth step being carried out in the same technological apparatus.

2. Method for producing a multilayer according to claim 1, characterised in that the second material supporting substrate is a second material substrate or a second material layer formed on a predetermined substrate.

3. Method for producing a multilayer according to claim 1, characterised in that it also includes, before the bonding step, a step of forming at least one additional layer on the first material layer.

4. Method for producing a multilayer according to claim 1, characterised in that the receiving substrate also comprises at least one layer on its bonding surface.

5. Method for producing a multilayer according to claim 1, characterised in that the surface of the second material supporting substrate comprising the first material layer and/or the bonding surface of the receiving substrate also comprise(s) a Bragg mirror formed by an alternation of thin films with different refraction indices n₁ and n₂.

6. Method for producing a multilayer according to claim 1, characterised in that the step of partially removing the initial substrate is carried out by the implantation, prior to the bonding step, of gaseous species in the second material supporting substrate, and by performing thermal annealing of the implanted bonded structure obtained, at a temperature lower than the evaporation temperature of the second material and/or by applying mechanical stresses to the bonded implanted structure.

7. Method for producing a multilayer according to the previous claim, characterised in that the gaseous species are selected from H, He, noble gases, and so on.

8. Method for producing a multilayer according to claim 1, characterised in that the step of partially removing the initial substrate is carried out by a mechanical-chemical thinning of said initial substrate until a second material thin film is obtained on the first material layer.

9. Method for producing a multilayer according to claim 1, characterised in that the step of growing said at least one layer on the first material layer is carried out by molecular beam epitaxy (MBE) or by metal organic chemical vapour deposition (MOCVD), or by PECVD.

10. Method for producing a multilayer according to claim 1, characterised in that the first material is AlAs, Si, etc.

11. Method for producing a multilayer according to claim 1, characterised in that the second material is GaAs, SiₓGe₁₋ₓ, InP, Ge, etc.

12. Method for producing a multilayer according to claim 1, characterised in that the receiving substrate is made of a material selected from silicon, glass or ceramic.

13. Method for producing a multilayer according to claim 1, characterised in that the at least one layer formed on the bonded first material layer is made of a material selected from GaAs, AlAs, Si, SiGe or SiO₂.

14. Resonant cavity structure characterised in that it includes an active layer, which transmits or detects light, interposed between two reflecting mirrors, which structure is produced using the method of production according to claim 1.

15. Resonant cavity structure according to the previous claim, characterised in that the two reflecting mirrors are Bragg mirrors obtained from thin films of which the materials are selected from Si₃N₄, SiO₂, TiO₂, Si or HfO₂.
